(19) United States
(12) Patent Application Publication
(10) Pub. No.: US 2025/0385222 A1
(43) Pub. Date: Dec. 18, 2025

(54) HIGH-BANDWIDTH INTEGRATED CIRCUIT PACKAGING OF MEMORY AND LOGIC

(71) Applicant: QUALCOMM Incorporated, San Diego, CA (US)

(72) Inventors: Jihong CHOI, San Diego, CA (US); Hyun LEE, San Diego, CA (US); Giridhar NALLAPATI, San Diego, CA (US); Mustafa BADAROGLU, San Diego, CA (US); Zhongze WANG, San Diego, CA (US); Woo Tag KANG, San Diego, CA (US); Periannan CHIDAMBARAM, San Diego, CA (US)

(21) Appl. No.: 18/743,068

(22) Filed: Jun. 13, 2024

(51) Int. Cl. H01L 25/065; H01L 23/00; H01L 23/498; H10B 80/00

(52) U.S. Cl. CPC H01L 25/0652; H01L 23/49822; H01L 23/49838; H01L 24/16; H01L 24/48; H01L 24/73; H01L 2224/16145; H01L 2224/16225; H01L 2224/48139; H01L 2224/48155; H01L 2224/73257; H01L 2924/01029; H01L 2924/1434; H01L 2924/1436; H01L 2924/182; H10B 80/00

(57) ABSTRACT

An integrated circuit package is provided in which a stack of memory dies couples to a redistribution layer through a plurality of wire bonds or metal pillars. The redistribution layer is configured to support the signaling between the memory dies and a logic die within the integrated circuit package.

### TECHNICAL FIELD

The present application relates generally to integrated circuit packaging, and more specifically, to a high-bandwidth integrated circuit packaging of memory and logic.

### BACKGROUND

The combination of edge computing and artificial intelligence (AI) applications has led to the development of edge AI devices such as sensors in automotive applications, edge-AI-enabled cellular telephones, or Internet of Things (IOT) devices. Prior to the development of edge AI, the engine of an edge computing device (e.g., a microcontroller unit) would typically need to upload data to the cloud for AI processing. But with machine learning built into an edge AI device, the AI processing remains on the device so as to significantly decrease latency, reduce power consumption, and increase data security. In an edge AI device, a data connection from a logic circuit such as the microcontroller unit to its associated memories such as dynamic random-access memories (DRAMs) should have a relatively large bandwidth to accommodate the large amounts of data that travels back and forth from the logic circuit to the memories.

The logic circuit and the DRAMs are typically integrated into separate semiconductor dies. The resulting packaging of the logic die and the DRAM dies into a single integrated circuit package faces significant challenges in maintaining a small form factor and satisfying the relatively large bandwidth needed for the data flow between the logic die and the DRAM dies.

### SUMMARY

In accordance with an aspect of the disclosure, an integrated circuit package is provided that includes: a redistribution layer; a logic die coupled to a first surface of the redistribution layer through a first plurality of interconnects; and a plurality of memory dies arranged into a stack, the plurality of memory dies coupled to the first surface of the redistribution layer through a second plurality of interconnects.

In accordance with another aspect of the disclosure, an integrated circuit package is provided that includes: an upper redistribution layer; at least one stack of memory dies; a plurality of wire bonds coupled between the at least one stack and the upper redistribution layer; a lower redistribution layer coupled to the upper redistribution layer through a plurality of through-mold vias; a logic die; and a plurality of interconnects coupled between an active surface of the logic die and an upper surface of lower redistribution layer.

Finally, in accordance with another aspect of the disclosure, an integrated circuit package is provided that includes: an upper redistribution layer; at least one stack of memory dies; a first plurality of metal pillars coupled between the at least one stack and the upper redistribution layer; a lower redistribution layer coupled to the upper redistribution layer through a plurality of through-mold vias; a logic die; and a plurality of interconnects coupled between an active surface of the logic die and an upper surface of the lower redistribution layer.

These and other advantageous features may be better appreciated through the following detailed description.

### BRIEF DESCRIPTION OF THE DRAWINGS

FIG. 1 illustrates a side-by-side integrated circuit package of a logic die and a stack of memory dies coupled together through a redistribution layer in which the stack of memory dies couple to the redistribution layer through laterally-extending wire bonds in accordance with an aspect of the disclosure.

FIG. 2A illustrates the formation of the redistribution layer of the side-by-side package of FIG. 1 in accordance with an aspect of the disclosure.

FIG. 2B illustrates the stacking of the memory dies on the redistribution layer of FIG. 2A followed by the wire bonding of the memory dies to the redistribution layer in accordance with an aspect of the disclosure.

FIG. 2C illustrates the coupling of the logic die to the redistribution layer of FIG. 2B in accordance with an aspect of the disclosure.

FIG. 3 illustrates a side-by-side integrated circuit package of a logic die and a stack of memory dies coupled together through a redistribution layer in which the stack of memory dies couple to the redistribution layer through vertical wire bonds or metal pillars in accordance with an aspect of the disclosure.

FIG. 4A illustrates a stage in the manufacture of the package of FIG. 3 in which the stack of memory dies of FIG. 3 are secured onto a carrier substrate in accordance with an aspect of the disclosure.

FIG. 4B illustrates a stage in the manufacture of the package of FIG. 3 including the coupling of the vertical wire bonds to the stack of memory dies in accordance with an aspect of the disclosure.

FIG. 4C illustrates another stage in the manufacture of the package of FIG. 3 including the securing of the logic die to the carrier substrate in accordance with an aspect of the disclosure.

FIG. 4D illustrates another stage in the manufacture of the package of FIG. 3 including the encapsulation of the logic die and the stack of memory dies in mold compound followed by a grinding and polishing of the mold compound surface in accordance with an aspect of the disclosure.

FIG. 4E illustrates another stage in the manufacture of the package of FIG. 3 including the deposition of the redistribution layer onto the polished mold compound surface in accordance with an aspect of the disclosure.

FIG. 5 illustrates a vertically stacked integrated circuit package including a logic die and stacks of memory dies in which the stacks of memory dies are wire bonded to an upper surface of an upper redistribution layer and in which the logic die is coupled through micro bumps or metal pillars to a lower surface of the upper redistribution layer in accordance with an aspect of the disclosure.

FIG. 6A illustrates a beginning stage in the manufacture of the vertically stacked integrated circuit package of FIG. 5 in which the lower redistribution layer is deposited and attached to through-mold vias in accordance with an aspect of the disclosure.

FIG. 6B illustrates a stage in the manufacture of the vertically stacked integrated circuit package of FIG. 5 in which the lower redistribution layer is further integrated with the logic die in accordance with an aspect of the disclosure.

FIG. 6C illustrates a stage in the manufacture of the vertically stacked integrated circuit package of FIG. 5 in which the logic die and through-mold vias are encapsulated with mold compound, a surface of the mold compound is ground and polished, and the upper redistribution layer deposited on the resulting polished mold compound surface in accordance with an aspect of the disclosure.

FIG. 6D illustrates a stage in the manufacture of the vertically stacked integrated circuit package of FIG. 5 in which the stacks of memory dies are secured and coupled to the upper redistribution layer with laterally extending wire bonds in accordance with an aspect of the disclosure.

FIG. 7 illustrates a vertically stacked integrated circuit package including a logic die and stacks of memory dies in which the stacks of memory dies are coupled through vertical wire bonds or metal pillars to an upper surface of an upper redistribution layer and in which the logic die is coupled through micro bumps or metal pillars to a lower redistribution layer in accordance with an aspect of the disclosure.

FIG. 8A illustrates a beginning stage in the manufacture of the vertically stacked integrated circuit package of FIG. 7 in which the stacks of memory dies are formed onto a carrier substrate in accordance with an aspect of the disclosure.

FIG. 8B illustrates a stage in the manufacture of the vertically stacked integrated circuit package of FIG. 7 in which the stacks of memory dies are coupled to the vertical wire bonds in accordance with an aspect of the disclosure.

FIG. 8C illustrates a stage in the manufacture of the vertically stacked integrated circuit package of FIG. 7 in which the stacks of memory dies are encapsulated with mold compound, a surface of the mold compound is ground and polished, and the upper redistribution layer deposited on the resulting polished surface in accordance with an aspect of the disclosure.

FIG. 8D illustrates a stage in the manufacture of the vertically stacked integrated circuit package of FIG. 7 in which through-mold vias are formed on the upper redistribution layer in accordance with an aspect of the disclosure.

FIG. 8E illustrates a stage in the manufacture of the vertically stacked integrated circuit package of FIG. 7 in which the logic die is secured to the upper redistribution layer in accordance with an aspect of the disclosure.

FIG. 8F illustrates a stage in the manufacture of the vertically stacked integrated circuit package of FIG. 7 in which the through-mold vias and logic die are encapsulated in mold compound, a surface of the mold compound is ground and polished, and the lower redistribution layer deposited on the resulting polished surface in accordance with an aspect of the disclosure.

FIG. 9 illustrates some example electronic systems including an integrated circuit package in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

In a 2.5D packaging of multiple dies into a single integrated circuit package, a top die (or top dies) connects through solder balls (bumps) to one or more lower dies. The resulting bump pitch (required separation between adjacent bumps) limits the bandwidth for the data flow to the top die. Side-by-side and vertical stack implementations of an integrated circuit package are disclosed herein that advantageously offer significantly improved bandwidth while maintaining a small form factor. Some example side-by-side implementations will be discussed first followed by a discussion of some example stacked implementations.

### Side-by-Side Integrated Circuit Package Including a Logic Die and Memory Dies

The logic die in an AI edge device will typically interface with multiple memory dies such as DRAM dies due to the relatively large amount of data needed for AI applications. The following discussion will be directed to the use of DRAM dies in the integrated circuit package, but it will be appreciated that other types of random access memory (RAM) dies such as magnetic RAM may be used in alternative implementations. To maintain a small footprint (package size), the DRAM dies herein are stacked above a redistribution layer. In a first side-by-side implementation, each DRAM die in the stack has its active surface including its transistors facing away from the redistribution layer. Each DRAM die's active surface includes conductive pads for forming an input/output interface to the DRAM die. To provide access to this input/output interface, the DRAM dies below a topmost die in each stack are staggered so that each successively-lower DRAM die in the stack has an uncovered lateral portion of its active surface on which the conductive pads may be accessed without being covered by the DRAM die immediately above it in the stack. A plurality of interconnects such as a plurality of wire bonds couples between the exposed conductive pads on the DRAM dies and the redistribution layer. Since each DRAM die's active surface faces away from the redistribution layer, each wire bond extends laterally and downwards from a conductive pad on the respective active surface to a corresponding conductive pad on the redistribution layer.

A logic die couples to the redistribution layer adjacent to the staggered DRAM die stack. For example, the logic die may couple to the redistribution layer in a flip chip fashion through a plurality of interconnects such as a micro bump array (e.g., a a copper or copper/tin micro bump array). Alternatively, metal pillars such as copper pillars may be used to couple the active surface of the logic die to the redistribution layer. A mold compound encapsulates the logic die, the staggered DRAM stack, the wire bonds, and the redistribution layer to complete the first side-by-side package implementation. The resulting coupling to the redistribution layer from the staggered DRAM stack through the laterally extending wire bonds advantageously accommodates a relatively high data speed for the data flow between the logic die and the DRAM dies. In addition, the staggered stacking of the DRAM dies advantageously achieves a small form factor for the resulting packaging.

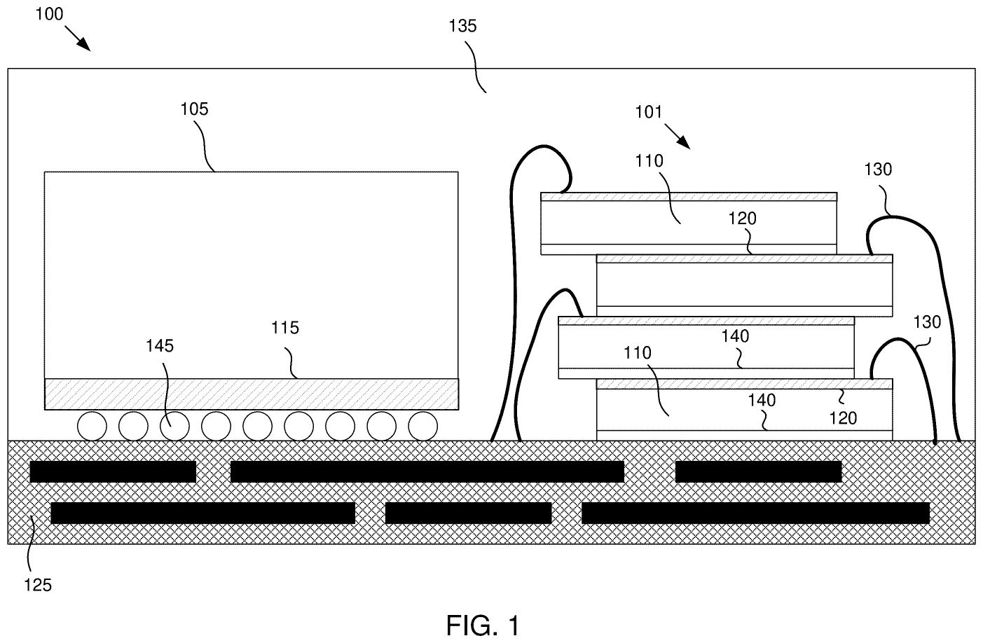

An example side-by-side package 100 with laterally extending wire bonds 130 to a staggered stack 101 of DRAM dies is shown in FIG. 1. A logic die 105 has its active surface 115 facing a redistribution layer 125. A plurality of interconnects such as a plurality of micro bumps 145 (e.g., copper or copper/tin micro bumps) couple between conductive pads (not illustrated) on the active surface 115 and the redistribution layer 125.

The redistribution layer 125 (and other redistribution layers disclosed herein) may be formed using a suitable dielectric polymer such as polyimide that is photolithographically patterned in either a positive or negative fashion. A conductive metal such as copper or titanium/copper may then be sputtered or electroplated onto the patterned dielectric polymer to form the desired electrical connections in the redistribution layer. The metal and dielectric may be layered so that multiple patterned metallic layers are present in the redistribution layer 125.

The staggered stack 101 of DRAM dies 110 is adjacent to or side-by-side with respect to the logic die 105 on the redistribution layer 125. Each DRAM die 110 has its active surface 120 facing away from the redistribution layer 125. A bonding layer 140 couples a back surface of each successively-higher DRAM die 110 in the stack 101 to its underlying DRAM die 110. Another bonding layer 140 couples a back surface of a bottom-most DRAM die 110 in the stack 101 to the redistribution layer 125.

The staggering of the stack 101 exposes a lateral portion of the active surface 120 of each underlying DRAM die 110 in the stack 101. For example, the bottom-most DRAM die 110 is displaced to the right with respect to the DRAM die 110 immediately above it. Wire bonds 130 may thus extend laterally from conductive pads (not illustrated) in the resulting exposed lateral portion of the active surface 120 of this bottom-most die 110 and loop down to corresponding conductive pads in the redistribution layer 125. The exposed lateral portions in successive-ones of the DRAM dies 110 may alternate from left to right as shown for stack 101. Alternatively, the exposed lateral portions may all be on the same side of the stack 101 as will be explained further herein. A mold compound 135 such as epoxy encapsulates the DRAM stack 101, the wire bonds 130, the redistribution layer 125, and the logic die 105.

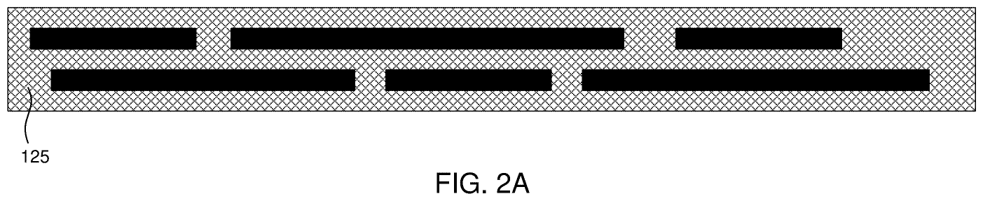

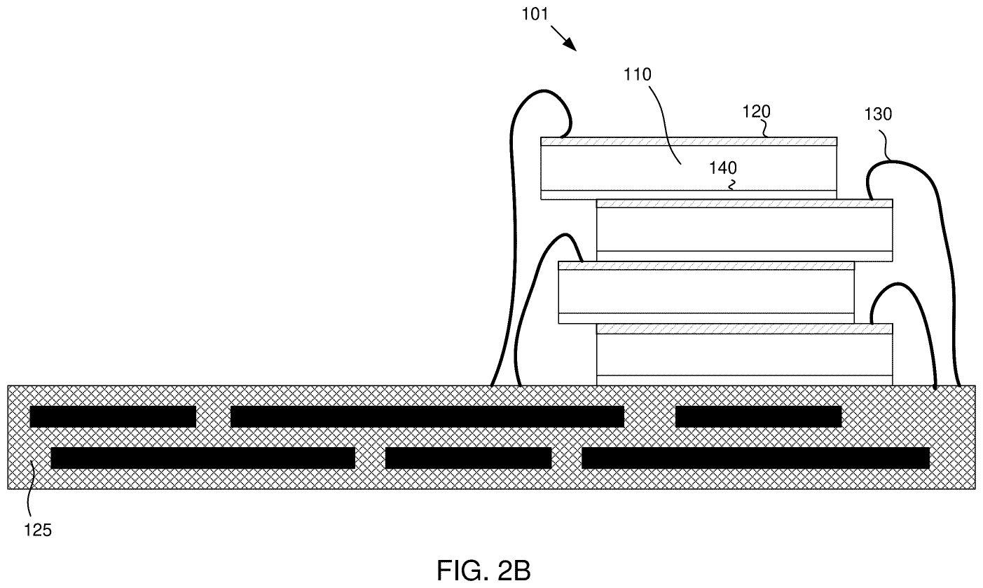

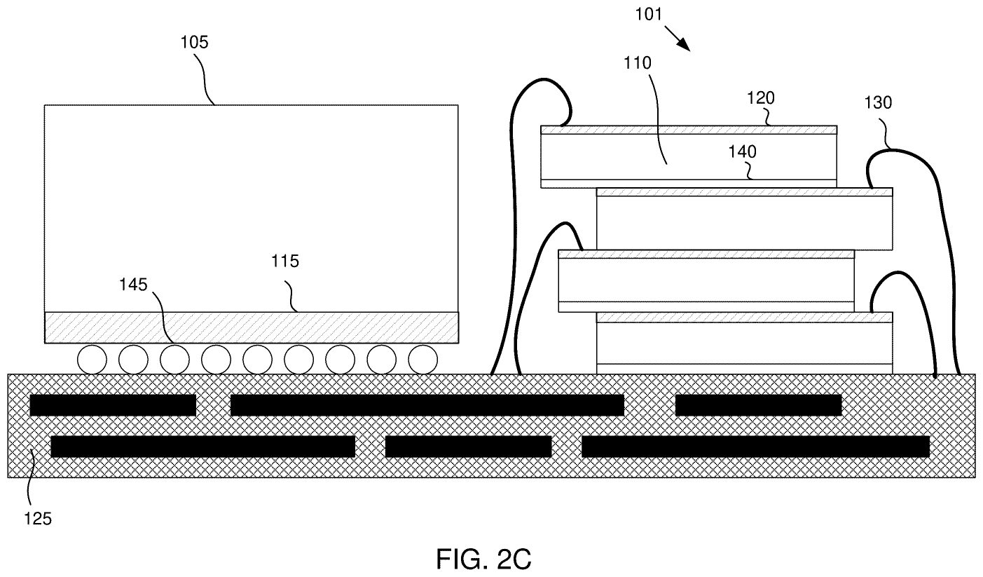

A fabrication process for the side-by-side integrated circuit package 100 will now be discussed. The process begins with the fabrication of the redistribution layer 125 on a carrier substrate (not illustrated) as shown in FIG. 2A. The carrier substrate may be wafer sized such that the resulting fabrication is a fan-out wafer-level co-packaging (FoWLcP) process. The DRAM dies 110 are then stacked onto the redistribution layer 125 in a staggered fashion as shown in FIG. 2B and secured through corresponding bonding layers 140 to form the stack 101. The conductive pads (not illustrated) on the exposed lateral portions of the active surface 120 for each DRAM die 110 is then wire bonded to corresponding conductive pads on the redistribution layer 125 through laterally extending wire bonds 130. As shown in FIG. 2C, the logic die 105 may then be bonded to corresponding conductive pads on the redistribution layer 125 through the micro-bumps 145. Referring again to FIG. 1, the dies 105 and 110 as well as the wire bonds 130 and the redistribution layer 125 are then encapsulated in the mold compound 135, an upper surface of the mold compound ground down so as to be flattened, and singulated to complete the side-by-side package 100.

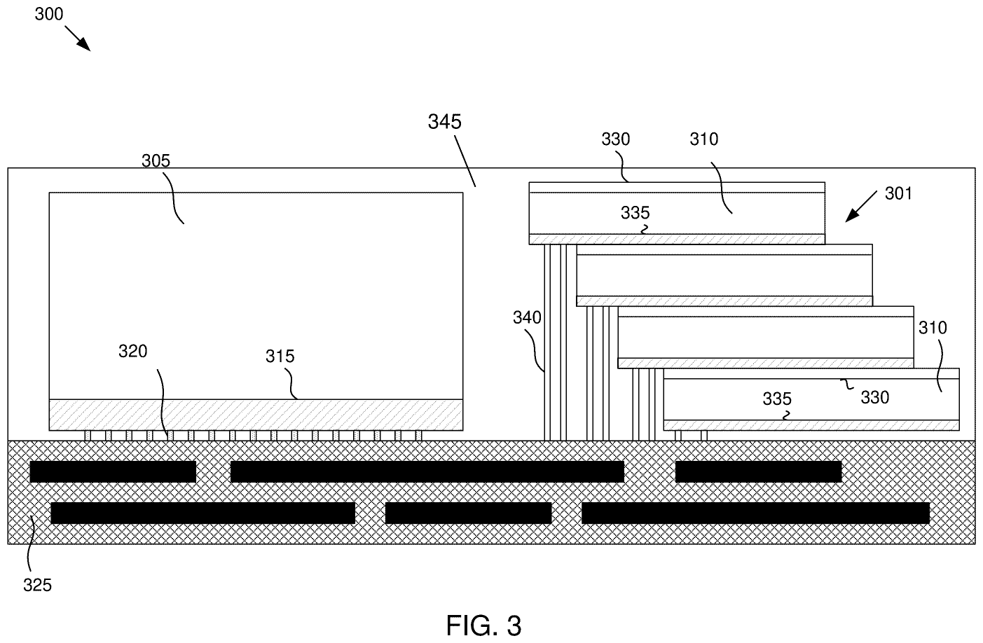

In an alternative example side-by-side integrated circuit package 300 as shown in FIG. 3, the wire bonds 130 of the integrated circuit package 100 may be replaced with a plurality of interconnects such as a plurality of vertical wire bonds 340. Vertical metal pillars may be used in place of the vertical wire bonds 340 in alternative implementations. The vertical wire bonds 340 couple between conductive pads (not illustrated) on an active surface 335 of each DRAM die 310 in a staggered stack 301 to corresponding conductive pads (not illustrated) on an upper surface of a redistribution layer 325. As compared to the laterally extending wire bonds 130, each vertical wire bond 340 does not extend laterally from its respective DRAM die 310. This vertical structure of the vertical wire bonds 340 allows for a tighter interconnect pitch as compared to the laterally extending wire bonds 130. The DRAM dies 310 are arranged in the stack 301 so that their active surfaces 335 face the redistribution layer 325. In contrast, the active surfaces 120 of the DRAM dies 110 in the stack 101 of the integrated circuit package 100 faced away from the redistribution layer 125. With the active surfaces 335 facing the redistribution layer 325, note that a left-and-right alternating staggering of the DRAM dies 310 as performed for stack 101 would be less effective in stack 301 because the exposed lateral portion of the active surface 335 of a DRAM die 310 from such a staggering may be shadowed by an underlying DRAM die 310. Thus, the staggering in stack 301 is one-sided instead of alternating sides. It doesn't matter if this one-sided staggering is consistently to the left or to the right. More generally, the lateral displacement of each successive DRAM die 310 in the stack 301 with respect to its preceding DRAM die 310 in the stack 301 is consistently in the same direction. In stack 301, this lateral direction is to the left from a bottom-most one of the DRAM dies 310. Each successively higher DRAM die 310 in the stack 301 thus is positioned laterally to the left of its underlying DRAM die 310. Each successive DRAM die 310 in the stack 301 will thus have a left-side lateral portion of its active surface 335 that is not shadowed or blocked by the underlying DRAM die 310 but instead faces the upper surface of the redistribution layer 325.

The vertical wire bonds 340 extend vertically from conductive pads on the exposed lateral portion of the active surface 335 of each successively-higher DRAM die 310 in the stack 301 to corresponding conductive pads on the redistribution layer 325. Although the entire active surface 335 of the bottom-most DRAM die 310 in the stack 301 is not shadowed, this bottom-most DRAM die 310 also has conductive pads on its lateral portion for consistency. The back surface of each DRAM die 310 is coated with a bonding layer 330 so that the stack 301 adheres together.

A logic die 305 has its active surface 315 facing the redistribution layer 325 in a flip-chip fashion. In package 300, conductive pads (not illustrated) on the active surface 315 couple to corresponding conductive pads (not illustrated) on the redistribution layer 325 through metal pillars 320. For example, metal pillars 320 (which may also be denoted as metal posts) may be copper, copper/titanium, or any other suitable conductive metal such as gold or silver. Alternatively, the logic die 305 may be coupled to the redistribution layer 325 through micro bumps analogous to micro bumps 145 of the package 100 in alternative implementations.

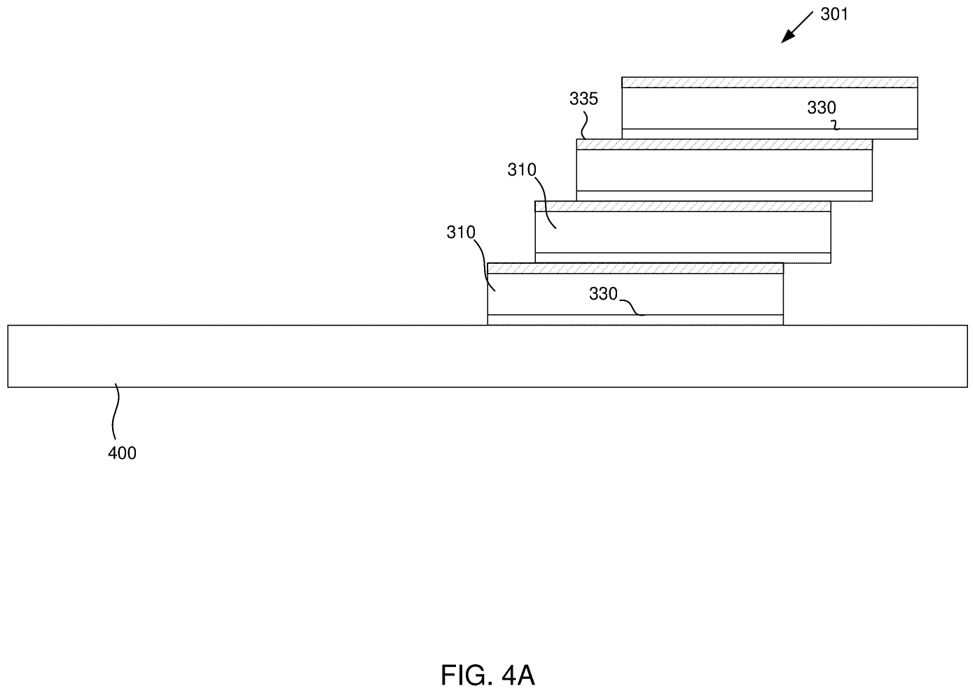

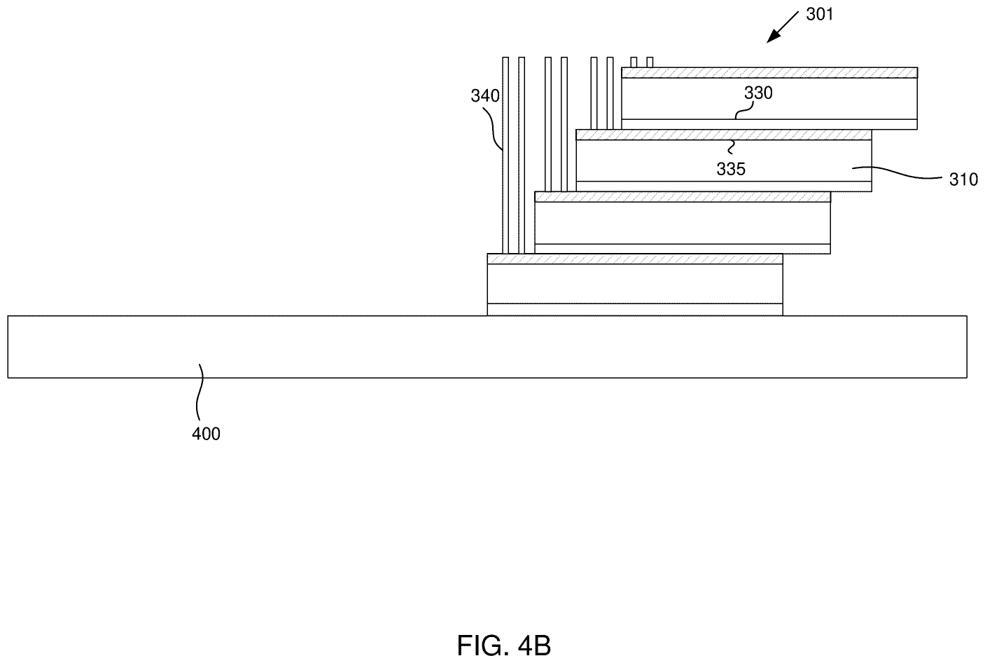

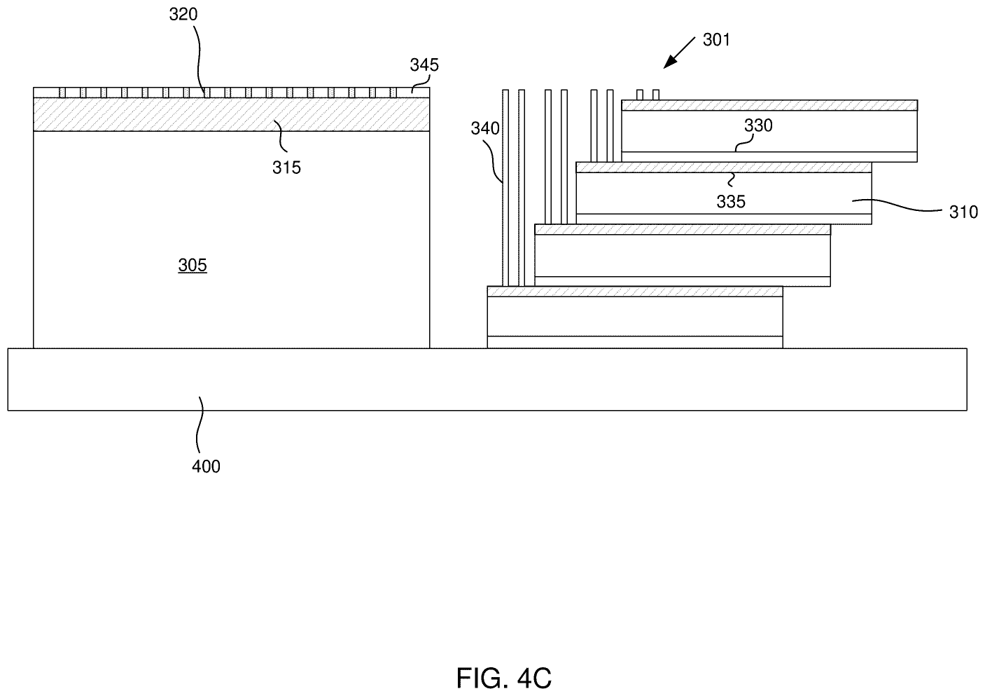

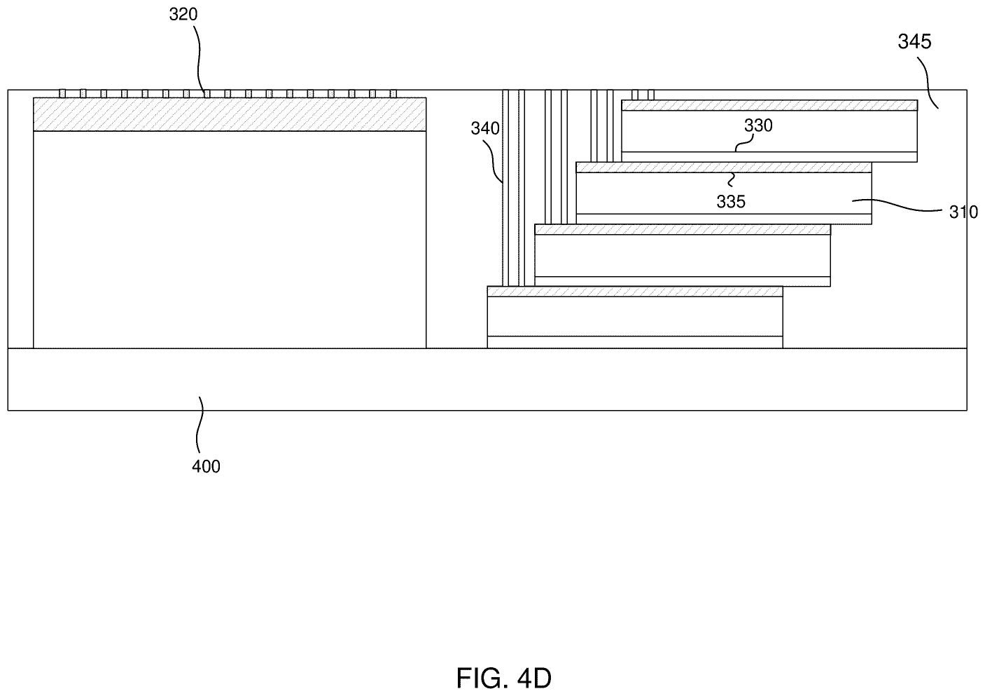

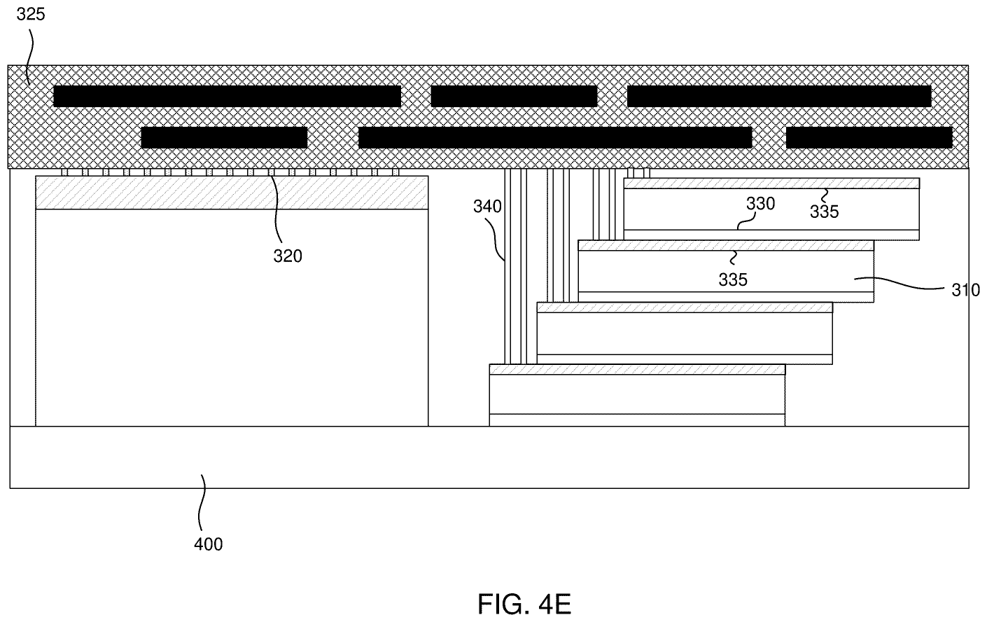

A fabrication process for the side-by-side integrated package 300 will now be discussed. The process begins with formation of the stack 301 on a carrier substrate 400 (e.g., a silicon carrier substrate) as shown in FIG. 4A. What will be the upper-most DRAM die 310 in the side-by-side package 300 attaches to the carrier substrate 400 through a corresponding bonding layer 330. Since stack 301 is top-side down with respect to the carrier substrate 400, the staggering of stack 301 is to the right side as compared to the left side staggering in the side-by-side package 300. The active surface 335 of each DRAM die 310 faces away from the carrier substrate 400.

The formation of the vertical wire bonds 340 is shown in FIG. 4B. A suitable wire bonding machine bonds the vertical wire bonds to corresponding conductive pads (not illustrated) on the exposed lateral portions of the active surfaces 335 of the DRAM dies 310. Alternatively, a seed layer of metal such as copper may be deposited over these exposed lateral portions followed by the deposition of a photoresist layer. The photoresist layer is then patterned with vias so that the vias may be electroplated with metal (e.g., copper) to form metal pillars in lieu of the vertical wire bonds 340. The photoresist layer is then removed followed by a light etching to remove the remaining seed layer to complete the metal pillars.

As shown in FIG. 4C, a back side of the logic die 305 is secured to the carrier substrate 400 adjacent to the stack 301. The metal pillars 320 are formed on the active surface 315 of the logic die 305 and encased in the mold compound 345. Additional mold compound 345 is added as shown in FIG. 4D to encase the logic die 305, the vertical wire bonds 340 and the stack 301. The mold compound 345 is then ground and polished flat so that the redistribution layer 325 may be deposited over the polished surface of the mold compound 345 as shown in FIG. 4E. The package 300 may then be singulated and removed from the carrier substrate 400 to complete its manufacture. Since the carrier substrate 400 may be wafer sized, the resulting manufacture in parallel of a plurality of packages 300 with respect to such a wafer may be deemed to be a fan-out wafer level co-packaging (FoWLcP) process. Some example stacked implementations will now be discussed.

### Vertically Stacked Integrated Circuit Package Including a Logic Die and Memory Dies

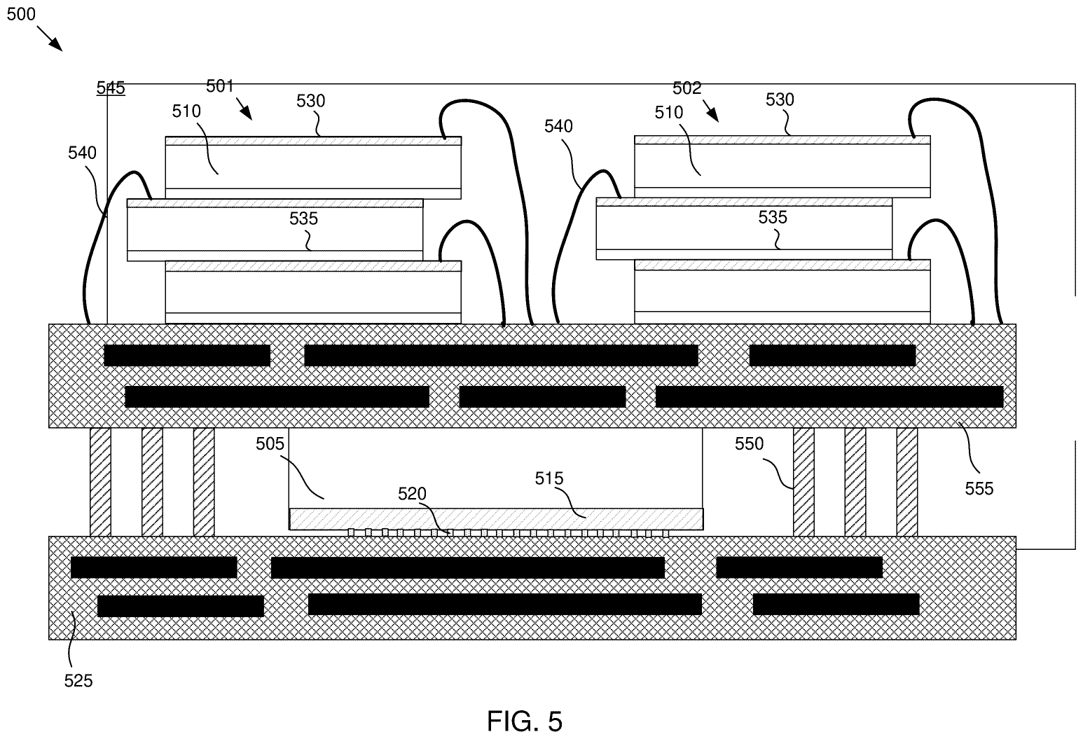

A first example vertically stacked integrated circuit package 500 is shown in FIG. 5. The stacked package 500 includes an upper redistribution layer 555, a lower redistribution layer 525, and a logic die 505 having an active surface facing the lower redistribution layer 525. The active surface 515 includes a plurality of conductive pads (not illustrated) coupled to corresponding conductive pads on the lower redistribution layer 525 through a plurality of interconnects such as a plurality of metal pillars 520 (e.g., copper, copper/titanium, gold, or silver metal pillars). Alternatively, metal pillars 520 may be replaced with micro bumps analogous to the micro bumps 145 of package 100.

An upper surface of the upper redistribution layer 555 includes a plurality of conductive pads (not illustrated) coupled to corresponding conductive pads (also not illustrated) on the active surfaces 530 of the stacked DRAM dies 510 through laterally extending wire bonds 540. The DRAM dies 510 are stacked to form at least one staggered stack in which the staggering alternates from left to right analogously as discussed for the stack 101 of package 100. Package 500 includes a first stack 501 and a second stack 502 but it will be appreciated that just one stack or more than two stacks may be included in alternative implementations. However, as the number of stacks increases, so does the resulting lateral size or extent of the package 500. The active surface 530 of each DRAM die 510 faces away from the upper redistribution layer 555. A bonding layer 535 bonds to the back side of each DRAM die 510 analogously as discussed for the bonding layers 140 in the stack 101.

A left-to-right alternation of the staggering in each of the stacks 501 and 502 exposes a lateral portion of the active surface 530 of each underlying DRAM die 510 in the stack 501 and 501. For example, the bottom-most DRAM die 510 in each of the stacks 501 and 502 is displaced to the right with respect to the DRAM die 510 immediately above it. Wire bonds 540 may thus extend laterally from conductive pads (not illustrated) in the resulting exposed lateral portion of the active surface 530 of this bottom-most die 510 and loop or arc down to corresponding conductive pads in the upper redistribution layer 555. The exposed lateral portions in successive ones of the DRAM dies 510 may alternate from the left to right of the dies as shown for the stacks 501 and 502.

Conductive pads (not illustrated) on a lower surface of the upper redistribution layer 555 couple though interconnects such as through-mold vias 550 to corresponding conductive pads (not illustrated) on an upper surface of the lower redistribution layer 555. Interconnects (not illustrated) such as bumps, micro bumps, or metal pillars coupled to conductive pads (not illustrated) on a lower surface of the lower redistribution layer 525 may conduct signals, power, and ground between the package 500 and external circuits. A mold compound 545 such as epoxy encapsulates the stacks 501 and 502, the wire bonds 540, the upper redistribution layer 555, the through-mold vias 550, the logic die 505, and the lower redistribution layer 525.

A read of data from one of the DRAM dies 510 starts with the propagation of the data from the die's active surface 530 through the corresponding wire bonds 540, then through metal leads in the upper redistribution layer 555 to the corresponding through-mold vias 550 to propagate to the lower redistribution layer 525, then through metal leads in the lower redistribution layer 525 to corresponding ones of the metal pillars 520 to be received by the active layer of the logic die 505. A write operation occurs in the reverse order. Regardless of whether the data propagates in a read or a write operation, it is not subjected to the bandwidth-limiting effect of bumps as would occur in a traditional 2.5D integrated circuit package. The vertically stacked integrated circuit package 500 thus supports a high bandwidth for this coupling or signaling analogously as discussed for the side-by-side integrated circuit package 100 and also has an analogous compact footprint. Moreover, the use of the wire bonds 540 as well as the redistribution layers 525 and 555 in the integrated circuit package 500 lowers costs as compared to a traditional 3D integrated circuit package.

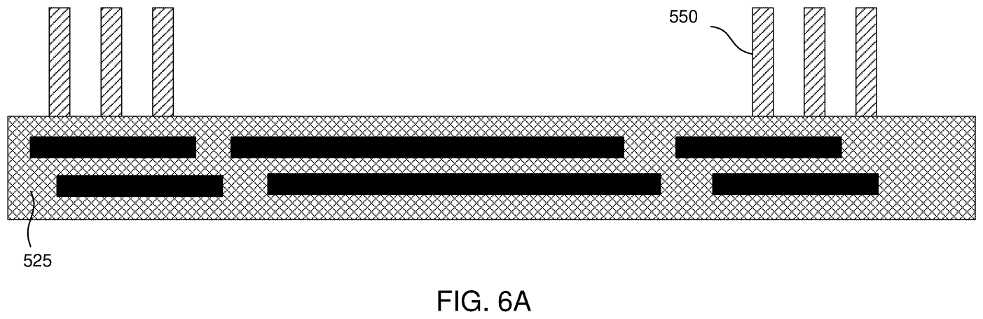

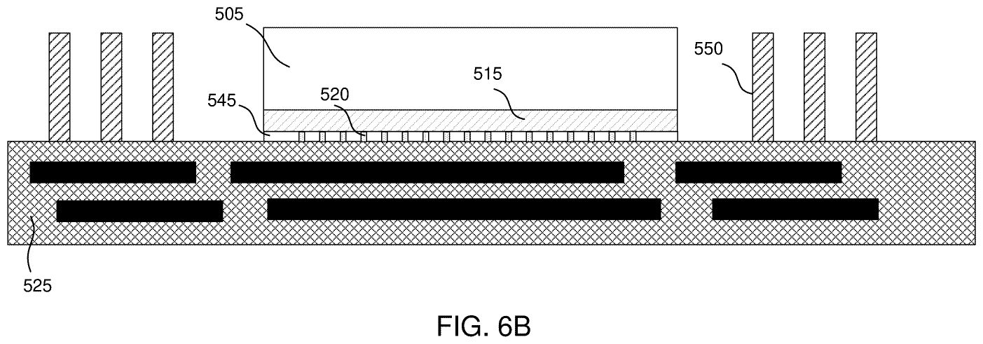

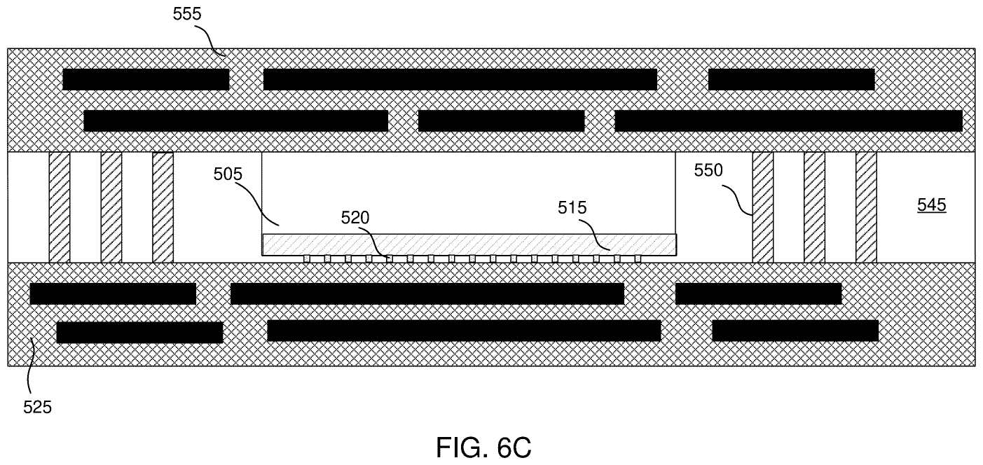

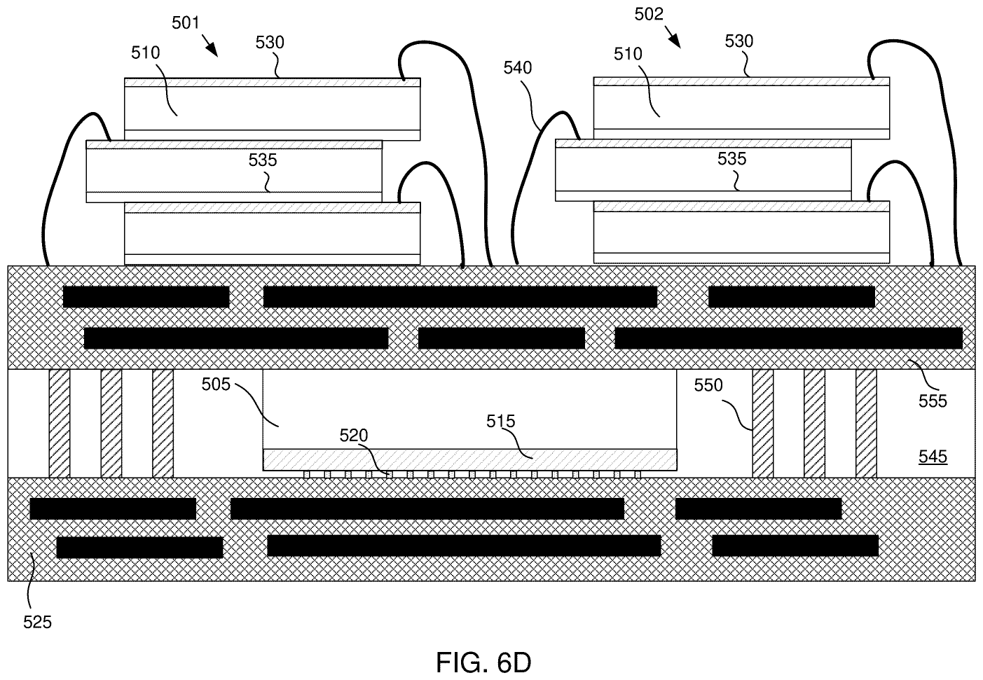

An example process of manufacturing for package 500 will now be discussed. The process begins as shown in FIG. 6A with the deposition of the lower redistribution layer 525 such as on a carrier substrate (not illustrated). To form the through-mold vias 550, a seed layer of a suitable metal such as copper is then deposited over the upper surface of the lower redistribution layer 525 followed by the deposition of a photoresist layer. The photoresist layer may then be patterned to form vias in the photoresist layer at the desired locations for the through-mold vias 550, followed by an electroplating or vapor deposition of a suitable metal such as copper in the vias. The photoresist is then removed followed by a light etching to remove any remaining exposed seed layer to complete the formation of the through-mold vias 550.

As shown in FIG. 6B, the logic die 505 is then coupled to the upper surface of the lower redistribution layer 525 through the metal pillars 520. Prior to this coupling, the active surface 515 of the logic die 505 may be pre-populated with the metal pillars 520 and encased in the mold compound 545. With the logic die 505 coupled to the lower redistribution layer 525, the through-mold vias 550 and the logic die 510 is encapsulated with additional mold compound 545, an upper surface of the mold compound 545 is ground and polished flat, and the upper redistribution layer 555 deposited over the polished upper surface of the mold compound 545 as shown in FIG. 6C. As shown in FIG. 6D, the stacks 501 and 502 of the DRAM dies 510 are then secured on the upper surface of the upper redistribution layer 555 followed by the formation of the wire bonds 540. Finally, additional mold compound 545 is deposited to encapsulate the stacks 501 and 502 and also the wire bonds 540 followed by the singulation of the package 500 to complete its manufacture. Due to the fan out through the redistribution layers 555 and 525, the resulting manufacture of the vertically stacked integrated circuit package 500 may be deemed to be a FoWLcP process.

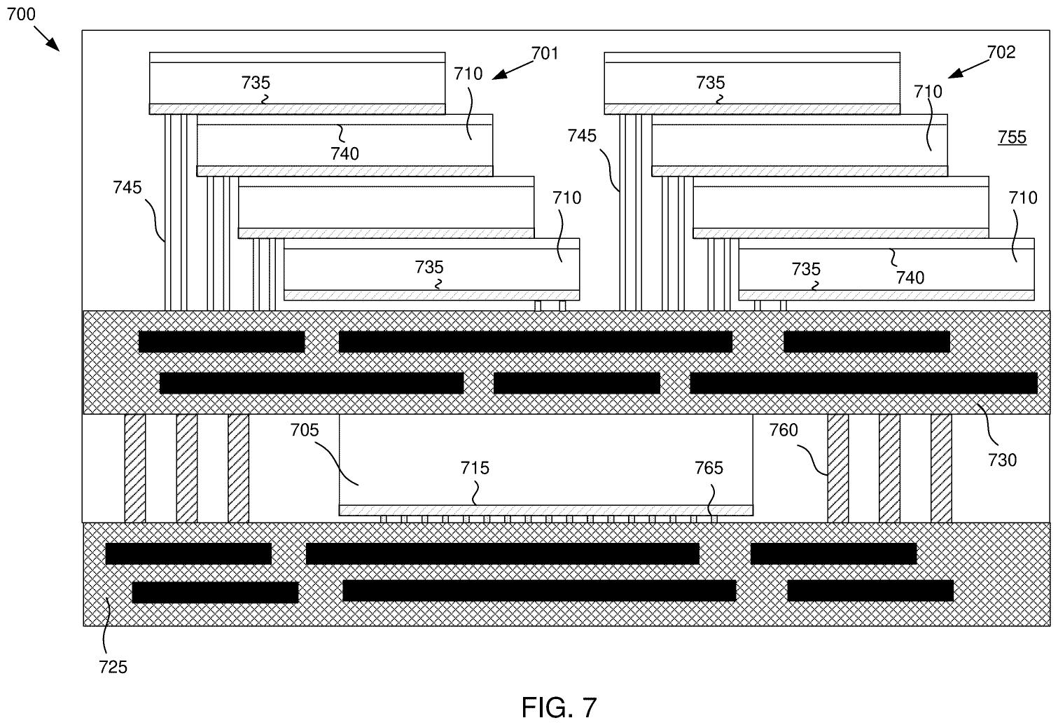

In an alternative example vertically stacked integrated circuit package 700 as shown in FIG. 7, the wire bonds 540 of package 500 may be replaced with vertical wire bonds 745 that couple between conductive pads (not illustrated) on active surfaces 735 of stacked DRAM dies 710 and conductive pads (not illustrated) on an upper surface of an upper redistribution layer 730. The DRAM dies 710 are stacked to form a first stack 701 and a second stack 702 but it will be appreciated that just one stack or more than two stacks may be included in alternative implementations of package 500. The stacks 701 and 702 are analogous to stack 301 of the integrated circuit package 300 in that the staggering from one DRAM die to the next in each stack 701 and 702 is one-sided and does not alternate from left to right.

The DRAM dies 710 are stacked so that their active surfaces 735 face the upper redistribution layer 730. With the active surfaces 735 facing the upper redistribution layer 730, note that a left-and-right alternating staggering of the DRAM dies 710 as done for stack 101 would be less effective in stacks 701 and 702 because the exposed lateral portion of the active surface 735 of a DRAM die 710 from such a staggering may be shadowed by an underlying DRAM die 710. Thus, the staggering in stacks 701 and 702 is one-sided instead of alternating sides. It doesn't matter if this one-sided staggering is consistently to the left or to the right. In stacks 701 and 702, it is to the left from a bottom-most one of the DRAM dies 710. Each successively higher DRAM die 710 in the stacks 701 and 707 thus is positioned laterally to the left of its underlying DRAM die 710. Each successive DRAM die 710 in the stacks 701 and 702 will thus have a left-side lateral portion of its active surface 735 that is not shadowed by the underlying DRAM die 710 but instead faces the upper surface of the upper redistribution layer 730.

The vertical wire bonds 745 extend vertically from the conductive pads on the exposed lateral portion of the active surface 335 of each successively-higher DRAM die 710 in the stacks 701 and 702 to corresponding conductive pads on the redistribution layer 730. The back surface of each DRAM die 710 is coated with a bonding layer 740.

As discussed analogously for package 500, the upper redistribution layer 730 couples to a lower redistribution layer 725 through through-mold vias 760. A logic die 705 includes conductive pads (not illustrated) on its active surface 715 that couple to corresponding conductive pads (not illustrated) on an upper surface of the lower redistribution layer 725 through a plurality of interconnects such as a plurality of metal pillars 765. Alternatively, the metal pillars 765 may be replaced with micro bumps analogous to micro bumps 145 of package 100.

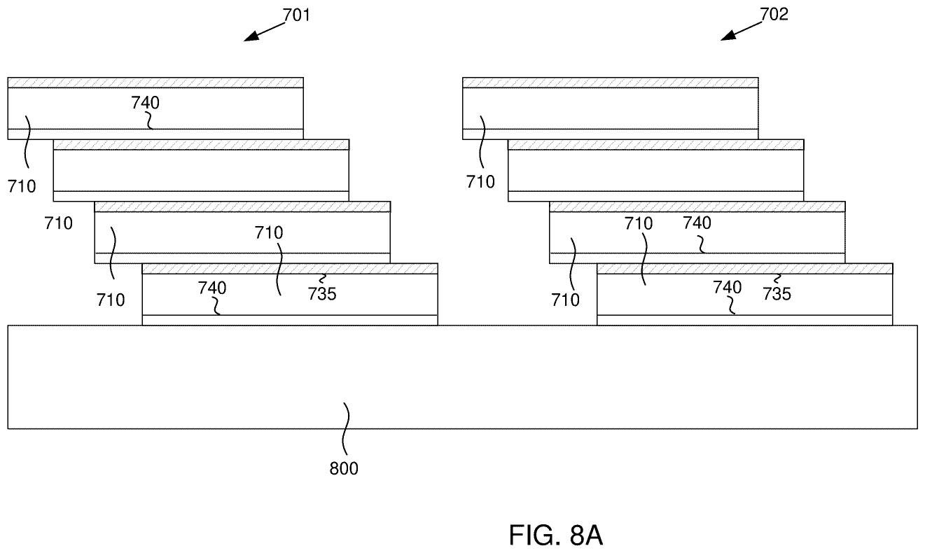

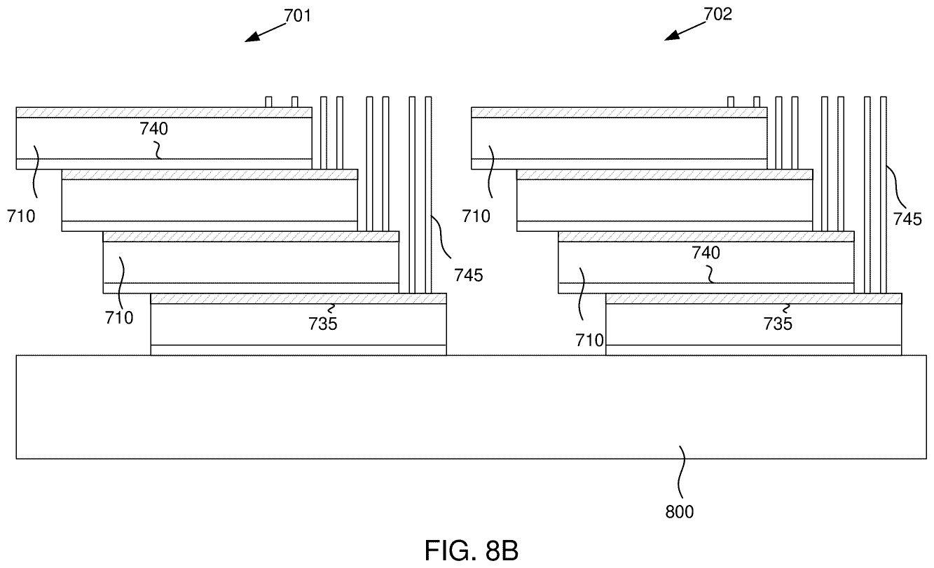

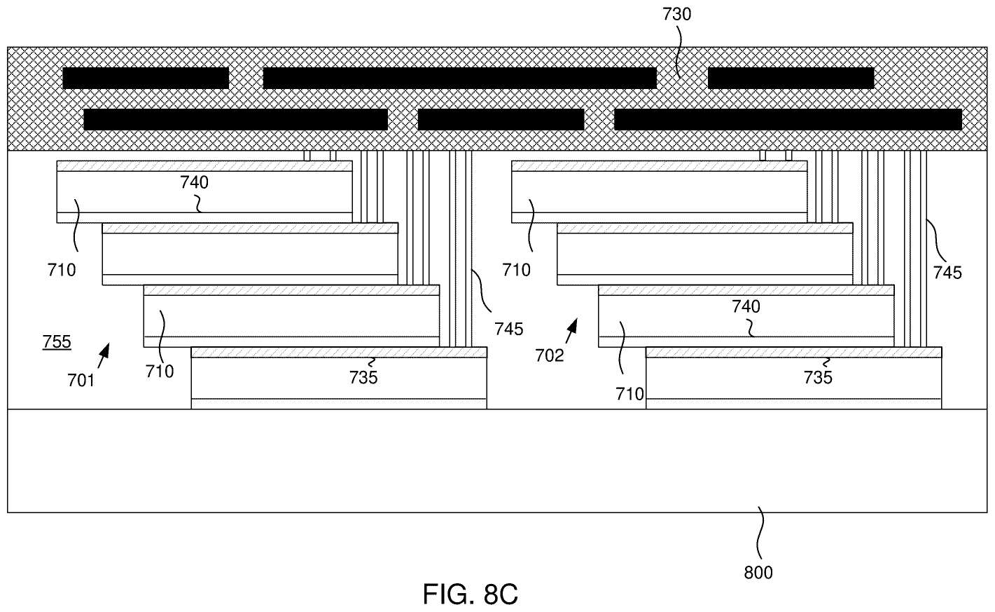

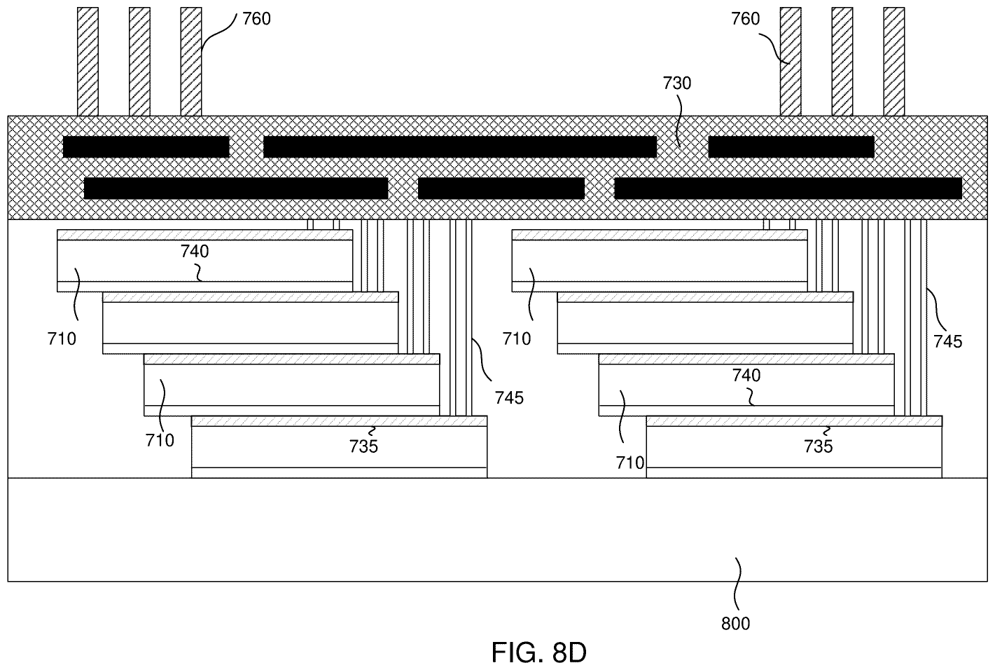

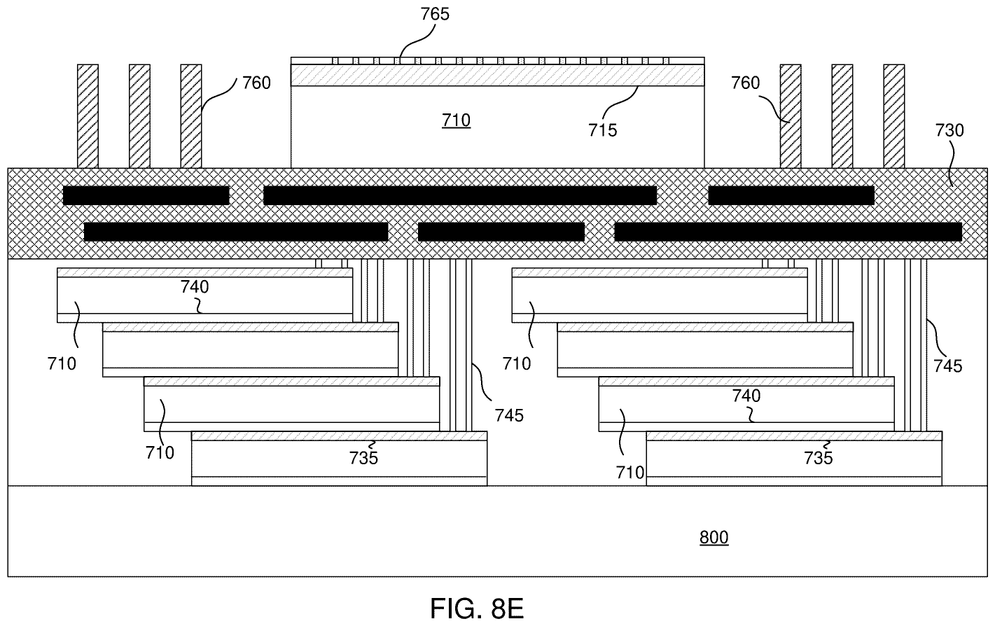

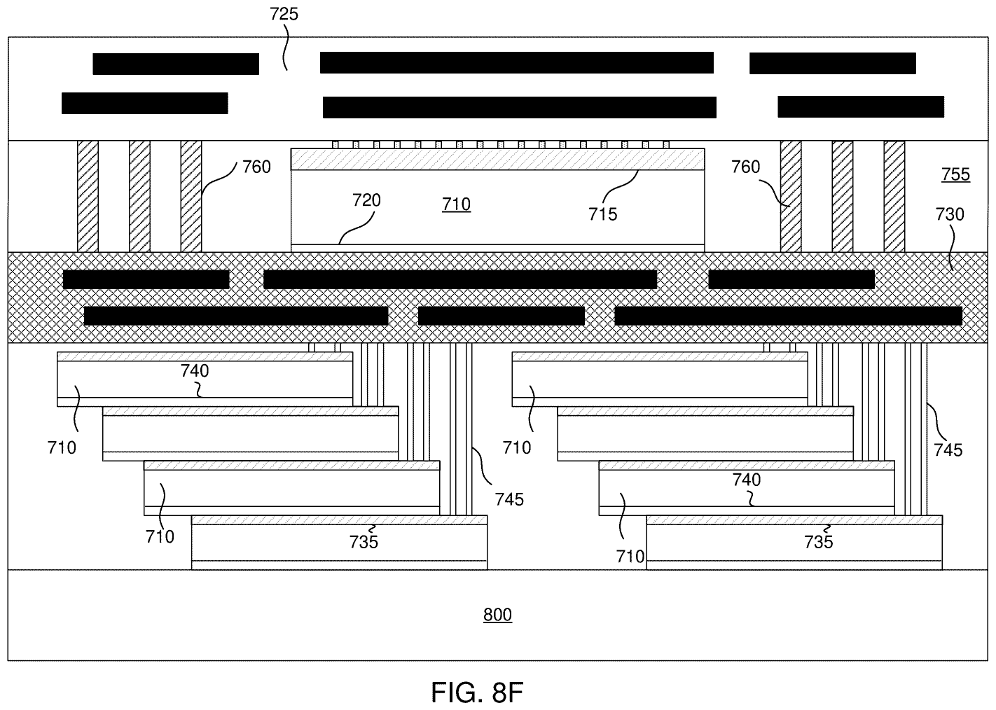

An example process of manufacturing the integrated circuit package 700 will now be discussed. As shown in FIG. 8A, the process begins with formation of the stacks 701 and 702 on a carrier substrate 800 (e.g., a silicon carrier substrate). What will be the upper-most DRAM die 710 in each of the stacks 701 and 702 attaches to the carrier substrate 800 through a corresponding bonding layer 740. The formation of the vertical wire bonds 745 is shown in FIG. 8B. A suitable wire bonding machine bonds the vertical wire bonds 745 to corresponding conductive pads (not illustrated) on the exposed lateral portions of the active surfaces 735 of the DRAM dies 710.

Alternatively, a seed layer of metal such as copper may be deposited over these exposed lateral portions followed by the deposition of a photoresist layer. The photoresist layer is then patterned with vias so that the vias may be electroplated with metal (e.g., copper) to form metal pillars in lieu of the vertical wire bonds 745. The photoresist layer is then removed followed by a light etching to remove the remaining seed layer to complete the metal pillars in such implementations.

As shown in FIG. 8C, the stacks 701 and 702 as well as the vertical wire bonds 745 are encapsulated with mold compound 755. After grinding flat and polishing of an upper surface of the mold compound 755, the upper redistribution layer 730 is deposited on this polished surface. As shown in FIG. 8D, the through-mold vias 760 may be formed analogously as discussed for through-mold vias 550. A back side of the logic die 710 may then be secured to the upper redistribution layer 730 as shown in FIG. 8E. Metal pillars 765 are deposited on the active surface 715 of the logic die 705 and encapsulated in mold compound prior to the securing of the logic die 705 to the upper redistribution layer 730. The through-mold vias 760 and logic die 705 are then encapsulated with additional mold compound 755 as shown in FIG. 8F, followed by a grinding and polishing of the mold compound 755 to form a polished surface for the deposition of the lower redistribution layer 725. The carrier substrate 800 is removed and the package 700 may then be singulated to complete its FoWLcP manufacture.

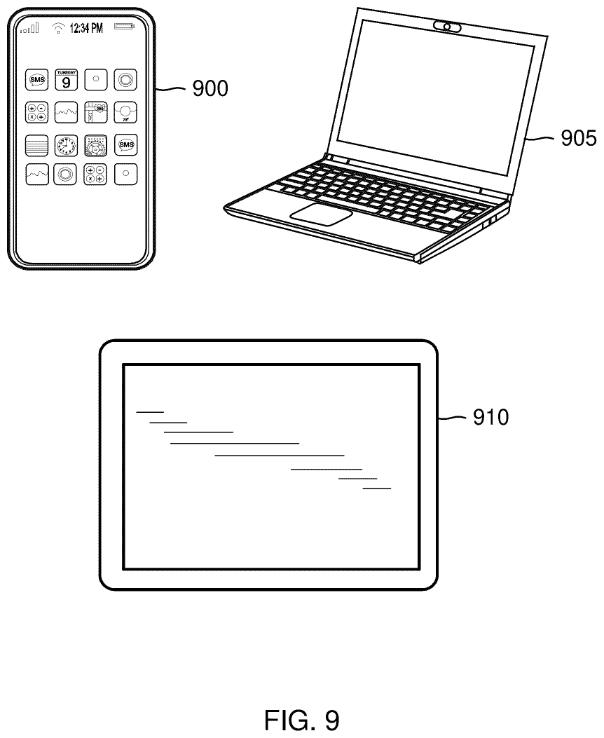

An integrated circuit package including a logic die and a plurality of memory dies as disclosed herein may be incorporated in a wide variety of electronic systems. For example, as shown in FIG. 9, a cellular telephone 900, a laptop computer 905, and a tablet 910 may all include an integrated circuit package in accordance with the disclosure. Other exemplary edge-AI-enabled electronic systems such as automotive sensors, video doorbells, and so on may also be configured with an integrated circuit package constructed in accordance with the disclosure.

Some example implementations are described by the following numbered clauses:

Clause 1. An integrated circuit package comprising:
a redistribution layer;
a logic die coupled to a first surface of the redistribution layer through a first plurality of interconnects; and
a plurality of memory dies arranged into a stack, the plurality of memory dies coupled to the first surface of the redistribution layer through a second plurality of interconnects.

Clause 2. The integrated circuit package of clause 1, wherein an active surface of the logic die faces the first surface of the redistribution layer.

Clause 3. The integrated circuit package of any of clauses 1-2, wherein the first plurality of interconnects comprises a plurality of micro bumps.

Clause 4. The integrated circuit package of clause 3, wherein the plurality of micro bumps comprises a plurality of copper micro bumps.

Clause 5. The integrated circuit package of any of clauses 1 and 3-4, wherein each memory die comprises a dynamic random-access memory die having an active surface facing away from the first surface of the redistribution layer.

Clause 6. The integrated circuit package of clause 5, wherein the dynamic random-access memory dies in the stack are staggered, and wherein the second plurality of interconnects comprises a plurality of wire bonds, each wire bond extending laterally from the stack to the first surface of the redistribution layer.

Clause 7. The integrated circuit package of clause 1, wherein each memory die comprises a dynamic random-access memory die having an active surface facing the first surface of the redistribution layer.

Clause 8. The integrated circuit package of clause 7, wherein each successive one of the dynamic random-access memory dies in the stack is displaced laterally in a first direction from a preceding one of the dynamic random-access memory dies in the stack, and wherein the second plurality of interconnects comprises a plurality of vertical wire bonds.

Clause 9. The integrated circuit package of clause 7, wherein each successive one of the dynamic random-access memory dies in the stack is displaced laterally in a first direction from a preceding one of the dynamic random-access memory dies in the stack, and wherein the second plurality of interconnects comprises a plurality of metal pillars.

Clause 10. An integrated circuit package, comprising:
an upper redistribution layer;
at least one stack of memory dies;
a plurality of wire bonds coupled between the at least one stack and the upper redistribution layer;
a lower redistribution layer coupled to the upper redistribution layer through a plurality of through-mold vias;
a logic die; and
a plurality of interconnects coupled between an active surface of the logic die and an upper surface of the lower redistribution layer.

Clause 11. The integrated circuit package of clause 10, wherein the plurality of interconnects comprises a plurality of metal pillars.

Clause 12. The integrated circuit package of any of clauses 10-11, wherein the integrated circuit package is incorporated into a cellular telephone.

Clause 13. The integrated circuit package of any of clauses 10-12, wherein each memory die comprises a dynamic random-access memory die having an active surface facing away from the upper surface of the upper redistribution layer.

Clause 14. The integrated circuit package of clause 13, wherein the dynamic random-access memory dies in the at least one stack are staggered, and wherein each wire bond in the plurality of wire bonds extends laterally from the at least one stack to the upper surface of the upper redistribution layer.

Clause 15. The integrated circuit package of clause 14, wherein each memory die comprises a dynamic random-access memory die having an active surface facing the upper surface of the upper redistribution layer, and wherein each wire bond in the plurality of wire bonds comprises a vertical wire bond.

Clause 16. An integrated circuit package, comprising:
an upper redistribution layer;
at least one stack of memory dies;
a first plurality of metal pillars coupled between the at least one stack and the upper redistribution layer;
a lower redistribution layer coupled to the upper redistribution layer through a plurality of through-mold vias;
a logic die; and
a plurality of interconnects coupled between an active surface of the logic die and an upper surface of the lower redistribution layer.

Clause 17. The integrated circuit package of clause 16, wherein the plurality of interconnects comprises a second plurality of metal pillars.

Clause 18. The integrated circuit package of any of clauses 16-17, wherein each memory die comprises a dynamic random-access memory die having an active surface facing the upper redistribution layer.

Clause 19. The integrated circuit package of clause 18, wherein each successive one of the dynamic random-access memory dies in the at least one stack is displaced laterally in a first direction from a preceding one of the dynamic random-access memory dies in the at least one stack.

Clause 20. The integrated circuit package of clause 18, wherein the first plurality of metal pillars comprises a plurality of electroplated copper posts.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. An integrated circuit package comprising:
a redistribution layer;
a logic die coupled to a first surface of the redistribution layer through a first plurality of interconnects; and
a plurality of memory dies arranged into a stack, the plurality of memory dies coupled to the first surface of the redistribution layer through a second plurality of interconnects.

2. The integrated circuit package of claim 1, wherein an active surface of the logic die faces the first surface of the redistribution layer.

3. The integrated circuit package of claim 2, wherein the first plurality of interconnects comprises a plurality of micro bumps.

4. The integrated circuit package of claim 3, wherein the plurality of micro bumps comprises a plurality of copper micro bumps.

5. The integrated circuit package of claim 1, wherein each memory die comprises a dynamic random-access memory die having an active surface facing away from the first surface of the redistribution layer.

6. The integrated circuit package of claim 5, wherein the dynamic random-access memory dies in the stack are staggered, and wherein the second plurality of interconnects comprises a plurality of wire bonds, each wire bond extending laterally from the stack to the first surface of the redistribution layer.

7. The integrated circuit package of claim 1, wherein each memory die comprises a dynamic random-access memory die having an active surface facing the first surface of the redistribution layer.

8. The integrated circuit package of claim 7, wherein each successive one of the dynamic random-access memory dies in the stack is displaced laterally in a first direction from a preceding one of the dynamic random-access memory dies in the stack, and wherein the second plurality of interconnects comprises a plurality of vertical wire bonds.

9. The integrated circuit package of claim 7, wherein each successive one of the dynamic random-access memory dies in the stack is displaced laterally in a first direction from a preceding one of the dynamic random-access memory dies in the stack, and wherein the second plurality of interconnects comprises a plurality of metal pillars.

10. An integrated circuit package, comprising:
an upper redistribution layer;
at least one stack of memory dies;
a plurality of wire bonds coupled between the at least one stack and the upper redistribution layer;
a lower redistribution layer coupled to the upper redistribution layer through a plurality of through-mold vias;
a logic die; and
a plurality of interconnects coupled between an active surface of the logic die and an upper surface of the lower redistribution layer.

11. The integrated circuit package of claim 10, wherein the plurality of interconnects comprises a plurality of metal pillars.

12. The integrated circuit package of claim 11, wherein the integrated circuit package is incorporated into a cellular telephone.

13. The integrated circuit package of claim 10, wherein each memory die comprises a dynamic random-access memory die having an active surface facing away from the upper surface of the upper redistribution layer.

14. The integrated circuit package of claim 13, wherein the dynamic random-access memory dies in the at least one stack are staggered, and wherein each wire bond in the plurality of wire bonds extends laterally from the at least one stack to the upper surface of the upper redistribution layer.

15. The integrated circuit package of claim 10, wherein each memory die comprises a dynamic random-access memory die having an active surface facing the upper surface of the upper redistribution layer, and wherein each wire bond in the plurality of wire bonds comprises a vertical wire bond.

16. An integrated circuit package, comprising:
an upper redistribution layer;
at least one stack of memory dies;
a first plurality of metal pillars coupled between the at least one stack and the upper redistribution layer;
a lower redistribution layer coupled to the upper redistribution layer through a plurality of through-mold vias;
a logic die; and
a plurality of interconnects coupled between an active surface of the logic die and an upper surface of the lower redistribution layer.

17. The integrated circuit package of claim 16, wherein the plurality of interconnects comprises a second plurality of metal pillars.

18. The integrated circuit package of claim 16, wherein each memory die comprises a dynamic random-access memory die having an active surface facing the upper redistribution layer.

19. The integrated circuit package of claim 18, wherein each successive one of the dynamic random-access memory dies in the at least one stack is displaced laterally in a first direction from a preceding one of the dynamic random-access memory dies in the at least one stack.

20. The integrated circuit package of claim 18, wherein the first plurality of metal pillars comprises a plurality of electroplated copper posts.
